(19) United States
(12) Patent Application Publication
(10) Pub. No.: US 2025/0308854 A1
(43) Pub. Date: Oct. 2, 2025

(54) STRUCTURAL MEMBER

(71) Applicant: TOTO LTD., Fukuoka (JP)

(72) Inventors: Yasutaka NITTA, Fukuoka (JP); Ryoto TAKIZAWA, Fukuoka (JP); Kenichi MOTOMURA, Fukuoka (JP)

(21) Appl. No.: 19/075,394

(22) Filed: Mar. 10, 2025

(30) Foreign Application Priority Data
Mar. 28, 2024 (JP) 2024-053349

(51) Int. Cl. H01J 37/32

(52) U.S. Cl. CPC H01J 37/32495; H01J 37/32467

(57) ABSTRACT

A structural member 10 has a base material 100 and a protective film 200 covering the surface Si of the base material 100. The protective film 200 is a film containing yttrium oxide as a main component, and an indentation hardness of the protective film 200 is 10 GPa or more.

### CROSS-REFERENCE TO RELATED APPLICATION

This application is based upon and claims the benefit of priority from Japanese Patent Application No. 2024-053349 filed on Mar. 28, 2024, the entire contents of which are incorporated herein by reference.

### FIELD

The present invention relates to a structural member.

### BACKGROUND

Structural members having a protective film on the surface of a base material are used in various fields such as semiconductor manufacturing equipment. For example, as described in Japanese Patent Laid-Open No. 2007-321183, in a semiconductor manufacturing equipment, a protective film is formed on the surface of a base material constructing an inner wall of a chamber for protecting the base material from plasma. For such a protective film, for example, oxide ceramics such as yttrium oxide (yttria) are used.

### SUMMARY

The protective film is the film for protecting a base material from plasma as described above and hence obviously needs to have sufficient durability against plasma. According to the experiments conducted by the present inventors, it has been verified that the lower the reactivity of the protective film to halogen (for example, fluorine) in plasma, the longer such a protective film can maintain the performance thereof. That is, the durability required for the protective film can also be said specifically halogen resistance.

The present inventors have verified that when the protective film is formed as a dense film having a low porosity, the halogen resistance of the protective film accordingly increases. Additionally, it has been also verified that when the protective film is the film containing yttrium oxide as the main component, the porosity of the protective film can be so low that pores cannot be observed as long as the indentation hardness of the protective film is increased to about 8 GPa.

For this reason, the present inventors have speculated that it is sufficient for the protective film containing yttrium oxide as the main component to have a Vickers hardness increased to about 8 GPa, and an even higher Vickers hardness than that does not enhance the halogen resistance of the protective film. However, for yielding the function of the protective film for a long period of time, it is desirable to further enhance the halogen resistance of the protective film.

The present invention has been achieved in view of such a problem, and an object thereof is to provide a structural member capable of maintaining the durability of the protective film against plasma for a long period of time.

For solving the above problem, the structural member according to the present invention has a base material and a protective film covering the surface of the base material. The protective film is the film containing yttrium oxide as the main component, and the indentation hardness of the protective film is 10 GPa or more.

The present inventors have continued further studies on the halogen resistance of the protective film and verified that there is room for further enhancing the halogen resistance of the protective film even after increasing the indentation hardness of the protective film to about 8 GPa and reducing the porosity of the protective film to the extent that pores cannot be observed. In other words, a novel finding was obtained that the halogen resistance of the protective film further enhances when the indentation hardness of the protective film is further more increased than the indentation hardness to the extent that pores cannot be observed in the protective film (that is, 8 GPa).

The indentation hardness of the protective film containing yttrium oxide as the main component increased to 10 GPa or more as described above enables to maintain the durability of the protective film for a longer period of time than before.

According to the present invention, the structural member capable of maintaining the durability of the protective film against plasma for a long period of time can be provided.

### BRIEF DESCRIPTION OF THE DRAWINGS

FIG. 1 schematically shows a cross-section of the structural member according to the present embodiment;

FIG. 2 shows a relationship table of the indentation hardness and the durability against plasma of the protective film;

FIG. 3A is an image obtained by capturing the cross-section of the protective film using a transmission electron microscope; and

FIG. 3B is an image obtained by capturing the cross-section of the protective film using a transmission electron microscope.

### DETAILED DESCRIPTION

Hereinafter, the present embodiments will be described in reference to the attached drawings. For easier understanding of the descriptions, in the drawings, the same elements are denoted by the same reference characters as much as possible, and a repeated description thereof may be omitted.

The structural member 10 according to the present embodiment is used as, for example, the member constructing an inner wall of a processing chamber in a semiconductor manufacturing equipment (not shown in the figures) such as a plasma etching system. Such an application of the structural member 10 is only an example and is not limited to the semiconductor manufacturing equipment.

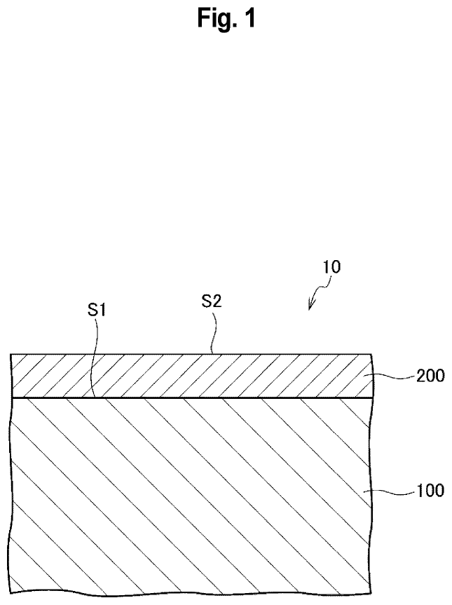

As shown in FIG. 1, the structural member 10 has a base material 100 and a protective film 200. In a plasma etching system and the like, the surface S2 of the protective film 200 is exposed toward the space in a chamber. The protective film 200 is provided for the purpose of protecting the surface S1 of the base material 100 from plasma.

The base material 100 is a member accounting for the majority of the structural member 10. In the present embodiment, the base material 100 is a ceramic sintered body containing a high purity aluminum oxide (Al₂O₃) but can also be formed of different types of ceramics from this. The surface S1 of the base material 100 is a flat surface in the present embodiment, but the surface S1 can have an unevenness, an inclined plane, or the like.

The protective film 200 is, as described above, the film formed to protect the base material 100 from plasma. The protective film 200 is formed in such a way as to cover throughout the entire surface S1 of the base material 100. The protective film 200 is a film containing yttrium oxide (Y₂O₃) as the main component and formed using physical vapor deposition (PVD) in the present embodiment. For ensuring the adhesion of the protective film 200 to the base material 100, the surface roughness of the surface S1 of the base material 100 may have Ra (arithmetic average roughness) of 0.5 μm or less. The method for forming the protective film 200 can be different from the method described above.

The thickness of the protective film 200 is suitably determined depending on the length of a period required to maintain the durability to plasma. In the present embodiment, the thickness of the protective film 200 is about 10 μm on average at each part. The thickness of the protective film 200 may be 3 μm or more and 50 μm or less on average at each part.

The protective film 200 is the film for protecting the base material 100 from plasma as described above and hence obviously needs to have sufficient durability against plasma. According to the experiments conducted by the present inventors, it has been verified that the lower the reactivity of the protective film 200 to halogen (for example, fluorine) in plasma, the longer the protective film 200 can maintain the performance thereof for a long period of time. That is, the durability required for the protective film 200 can also be said specifically halogen resistance.

When yttrium oxide composing the protective film 200 is fluoridated, the protective film 200 expands. In a semiconductor manufacturing equipment, when the protective film 200 repeatedly expands and contracts, many microcracks on the surface S2 are caused, whereby such a part is likely to become a source of particle generation. Considering this, the halogen resistance of the protective film 200 may be increased as much as possible.

The present inventors have verified that when the protective film 200 is formed as a dense film having a low porosity, the halogen resistance of the protective film 200 accordingly increases. Additionally, it has been also verified that when the protective film 200 is the film containing yttrium oxide as the main component as in the present embodiment, the porosity of the protective film 200 can be so low that pores cannot be observed as long as the indentation hardness of the protective film 200 is increased to about 8 GPa.

For this reason, the present inventors have speculated that it is sufficient for the protective film 200 containing yttrium oxide as the main component to have a Vickers hardness increased to about 8 GPa, and an even higher Vickers hardness than that does not enhance the halogen resistance of the protective film 200.

However, the present inventors have continued further studies on the halogen resistance of the protective film 200 and verified that there is room for further enhancing the halogen resistance of the protective film 200 even after increasing the indentation hardness of the protective film 200 to about 8 GPa and reducing the porosity of the protective film 200 to the extent that pores cannot be observed. In other words, a novel finding was obtained that the halogen resistance of the protective film further enhances, contrary to the above speculation, when the indentation hardness of the protective film 200 is further more increased than the indentation hardness to the extent that pores cannot be observed in the protective film 200 (that is, 8 GPa).

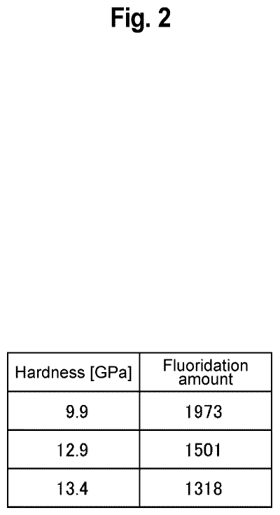

FIG. 2 shows the results of experiments conducted by the present inventors on the relationship between the indentation hardness and the halogen resistance of the protective film 200. The “fluoridation amount” shown in the same figure is the parameter indicating the fluoridation degree of the surface S2 when the surface S2 of the protective film 200 as a subject is exposed to plasma for a certain period of time. Specifically, it is the value obtained by measuring an amount of fluorine atoms present on the surface S2 using an X-ray photoelectron spectroscopy (XPS) while sputtering the surface S2 of the protective film 200 using argon. The measurement was carried out over a period of 145 seconds. At the measurement, the percentage of the measured value of argon to the whole (unit: %) is calculated at each time, and the integrated value of the obtained values is collected as the “fluoridation amount” in FIG. 2. Thus, it is considered that the smaller the value of the fluoridation amount shown in FIG. 2, the higher the halogen resistance of the protective film 200.

The present inventors formed protective films 200 under different film formation conditions respectively on several base materials 100 thereby to make several protective films 200 with different indentation hardnesses to each other. Subsequently, each protective film 200 was exposed to plasma for a certain period of time, and then the fluoridation amount described above was measured.

As a result, as shown in FIG. 2, when the indentation hardness of the protective film 200 was 9.9 GPa, the fluoridation amount of the protective film 200 was 1973. When the indentation hardness of the protective film 200 was 12.9 GPa, the fluoridation amount of the protective film 200 was 1501. When the indentation hardness of the protective film 200 was 13.4 GPa, the fluoridation amount of the protective film 200 was 1318.

Thus, it was verified that even when the indentation hardness of the protective film 200 was further increased from 8 GPa, the fluoridation amounts of the protective films 200 were not constant but decreased. That is, it was verified that the halogen resistance of the protective film 200 enhances when the indentation hardness of the protective film 200 is increased.

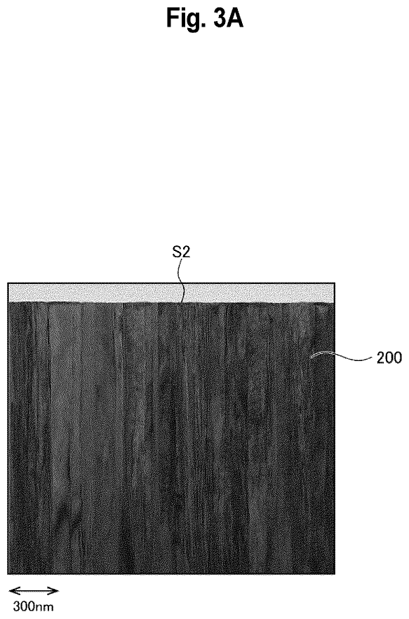

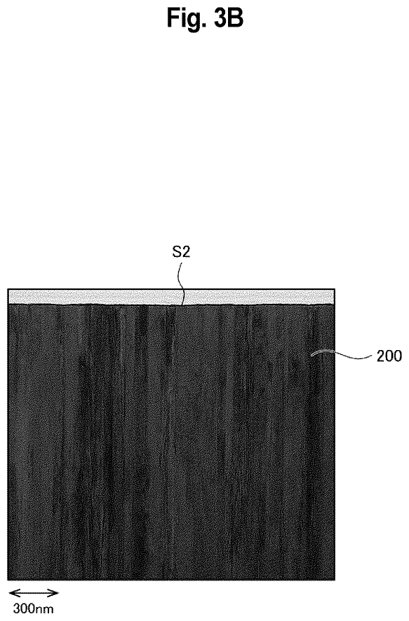

FIG. 3A shows the image obtained by capturing the cross-section of the protective film 200 having an indentation hardness of 9.9 GPa using a transmission electron microscope (TEM). Additionally, FIG. 3B shows the image obtained by culturing the cross-section of the protective film 200 having an indentation hardness of 13.4 GPa using a transmission electron microscope (TEM). As shown in FIG. 3A and FIG. 3B, no air bubble was observed in the cross-section of either of the above protective films 200.

As stated above, it was verified that when the indentation hardness of the protective film 200 is further increased even after the porosity of the protective film 200 is high and achieves a dense state to the extent of not observing air bubbles in the cross-section of the protective film 200, the halogen resistance of the protective film 200 accordingly enhances.

Thus, in the protective film 200 of the present embodiment, the indentation hardness thereof is increased to the extent that is considered “excess” in terms of the conventional finding described earlier thereby to increase the halogen resistance of the protective film 200 more than before. According to the further experiments conducted by the present inventors, it was verified that, as long as the indentation hardness of the protective film 200 is increased to 10 GPa or more, the durability of the protective film 200 against plasma sufficiently enhances, and such a durability can be maintained for a long period of time.

The indentation hardness of the protective film 200 is may be 11 GPa or more. Further, the indentation hardness of the protective film 200 may be 12 GPa or more. In a future, when the halogen resistance of the protective film 200 is required at a further higher level, the indentation hardness of the protective film 200 may be 12.5 GPa or more, and furthermore 13 GPa or more.

For the film formation method to increase the indentation hardness of the film as described above, known various findings on, for example, physical vapor deposition (PVD) and the like can be applied.

For example, when the protective film 200 is formed by physical vapor deposition, the film is formed while maintaining an internal pressure of a chamber for film formation low. The lower an internal pressure, the longer a mean free path of the gas, and thus the higher the collision energy when particles to be the protective film 200 collide against the base material 100, whereby consequently the protective film 200 with a high hardness can be formed.

As described above, when the protective film 200 is formed while maintaining an internal pressure low, oxygen having a smaller mass than yttrium is easily discharged from the chamber for film formation. For this reason, the oxygen content in the formed protective film 200 is likely to be lower than an oxygen content in yttrium oxide having a stoichiometric composition. That is, the ratio of the number of yttrium atoms to the number of oxygen atoms contained in the protective film 200 is likely to be a ratio different from 1:1.5, which is the stoichiometric ratio of yttrium oxide (Y₂O₃).

According to the experiment conducted by the present inventors, it is verified that when the film formation is carried out while adjusting the internal pressure so that the ratio of the number of yttrium atoms to the number of oxygen atoms contained in the protective film 200 is within the range of 1:1 to 1:1.26, the protective film 200 with satisfactory durability can be obtained.

In place of the above method, or in addition to the above method, the film formation can also be carried out while accelerating particles to be formed into the protective film 200 by a magnetic field or an electric field.

The indentation hardness of the protective film 200 can also be enhanced by adjusting other than the internal pressure. For example, the higher the temperature of the base material 100 is kept at the film formation, the higher the indentation hardness of the protective film 200 to be formed. In the case of forming the protective film 200 by chemical vapor deposition (CVD), the higher the plasma density, the higher the indentation hardness of the protective film 200 to be formed. Using these findings, the protective film 200 having an indentation hardness of 10 GPa or more can also be formed.

Hereinabove, the present embodiment has been described in reference to the specific examples. However, the present disclosure is not limited to these specific examples. Embodiments in which suitable design modifications are added to these specific examples by a person skilled in the art are also encompassed in the scope of the present disclosure as long as the features of the present disclosure are provided. Each element and the arrangements, conditions and shapes thereof included in each specific example described earlier are not limited to those given as examples and can be suitably modified. Each element included in each specific example described earlier can suitably have different combinations as long as technical contradictions do not arise.

What is claimed is:

1. A structural member comprising:
a base material, and
a protective film covering a surface of the base material,
wherein the protective film is a film containing yttrium oxide as a main component, and
an indentation hardness of the protective film is 10 GPa or more.

2. The structural member according to claim 1, wherein the protective film is a film formed by physical vapor deposition.

3. The structural member according to claim 1, wherein an oxygen content in the protective film is less than an oxygen content in the yttrium oxide having a stoichiometric composition.
